(19) United States
(12) Patent Application Publication
(10) Pub. No.: US 2004/0248346 A1
(43) Pub. Date: Dec. 9, 2004

(54) Inducing semiconductor crystallization using a capillary structure

(75) Inventors: Peter Rusian, Ashdod (IL); Arie Glazer, Mevaseret (IL); Mannie Dorfan, Nes Ziona (IL); Yoel Raab, Hod Hasharon (IL)

Correspondence Address: SUGHRUE MION, PLLC, 2100 PENNSYLVANIA AVENUE, N.W., SUITE 800, WASHINGTON, DC, 20037, US

(73) Assignee: ORBOTECH LTD

(21) Appl. No.: 10/857,887

(22) Filed: Jun. 2, 2004

Related U.S. Application Data
(60) Provisional application No. 60/474,612, filed on Jun. 2, 2003.

(51) Int. Cl. H01L 21/00

(52) U.S. Cl. 438/166

(57) ABSTRACT

A method for fabricating a semiconductor device includes providing a layer of a semiconductor material on at least a portion of a surface of a substrate, and forming along the surface a capillary structure, which is in communication with the semiconductor material but is at least partially empty of the semiconductor material. The semiconductor material is heated, so as to cause the semiconductor material to melt and flow into the capillary structure. Upon allowing the semiconductor material to cool, a crystal is seeded in the capillary structure and spreads from the capillary structure through an area of the semiconductor material.

### CROSS-REFERENCE TO RELATED APPLICATION

This application claims the benefit of the U.S. Provisional Patent Application No. 60/474,612, filed Jun. 2, 2003, whose disclosure is incorporated herein by reference.

### FIELD OF THE INVENTION

The present invention relates generally to fabrication of semiconductor devices, and specifically to formation of large grains of single-crystal semiconductor material on a device substrate.

### BACKGROUND OF THE INVENTION

Thin film transistors are used in a variety of applications, such as flat panel display screens. In some of these applications, it is desirable to form the transistors using large-grain single-crystal or polycrystalline silicon in the active region of each transistor. One way to produce crystallized silicon for this purpose is to deposit a layer of amorphous silicon (a-Si) on a substrate, and then anneal the silicon by laser heating.

For example, U.S. Pat. No. 6,573,531, whose disclosure is incorporated herein by reference, describes a system and method for producing single or polycrystalline silicon thin films using sequential lateral solidification. The system uses an excimer laser to melt portions of an amorphous silicon thin film at sequential locations.

PCT Patent Publication WO 03/071344 A1, whose disclosure is also incorporated herein by reference, describes a method for manufacturing flat panel display substrates with thin film transistors, using a non-excimer laser beam to form mutually-spaced-apart silicon crystals on the surface of the substrate. The laser energy heats the substrate at selected non-contiguous locations, but does not substantially heat other locations.

European Patent Application EP 1353363 A2, whose disclosure is incorporated herein by reference, describes a thin film transistor (TFT) and a method for fabricating the TFT. The method includes forming a line peninsular layer extending from an a-Si island layer at the active region of the TFT. A laser annealing process is then performed, so that re-crystallization of the silicon will occur starting from the line peninsular layer and then grow toward the silicon island, resulting in single crystallization of the silicon island.

### SUMMARY OF THE INVENTION

Embodiments of the present invention provide improved methods and structures for creating large-grain single-crystal thin films of semiconductor material on a substrate. A layer of a semiconductor material, such as amorphous silicon, is formed on the surface of the substrate, and a capillary structure is formed on the surface in communication with the semiconductor material. Typically, the capillary structure comprises a thin groove, which is initially at least partially empty of the semiconductor material. The groove may be formed in the substrate surface or built up above the substrate surface. The semiconductor material is then heated, by a laser beam, for example, which causes the material to melt and flow into the capillary structure by the force of capillary action. When heating is terminated, the molten material cools more rapidly in the capillary structure than on the surface outside the structure, so that the material solidifies into a crystal seed in the capillary structure. As the remaining material cools, the crystal grows from this seed to cover a relatively large area of the surface.

In some embodiments of the present invention, an array of “islands” of amorphous semiconductor material, such as a-Si, is deposited on the substrate, and an individual capillary structure is formed in communication with each island. Laser beam energy is delivered to the substrate so as to melt each of the islands and thus form an array of silicon crystals on the surface. These crystals may be used to form the active regions of an array of thin film transistors, for use in a flat panel display, for example.

The use of capillary flow to seed crystal formation on the surface of the substrate is advantageous in that it creates a single, well-defined nucleation center in a predetermined location for each crystal growth site (for example, each island in the embodiment described above). This technique permits large-grain single crystals to be formed with high reliability and consistent crystal orientation. It also affords a relatively wide process window for heat-induced creation of the crystals, since variations in temperature will typically affect only how far the molten material flows into the capillary before beginning to crystallize. Nucleation will begin in the capillary in any case, notwithstanding the temperature variation.

There is therefore provided, in accordance with an embodiment of the present invention, a method for fabricating a semiconductor device, including: providing a layer of a semiconductor material on at least a portion of a surface of a substrate; forming along the surface a capillary structure, which is in communication with the semiconductor material but is at least partially empty of the semiconductor material; heating the semiconductor material, so as to cause the semiconductor material to melt and flow into the capillary structure; and allowing the semiconductor material to cool to form a crystal in the semiconductor material.

Typically, the crystal is seeded in the capillary structure and spreads from the capillary structure through an area of the semiconductor material.

Typically, heating the semiconductor material includes bringing the semiconductor material to an overheated full melt. In a disclosed embodiment, providing the layer of the semiconductor material includes depositing amorphous silicon (a-Si) on the surface.

In disclosed embodiments, forming the capillary structure includes forming a plurality of non-contiguous capillary structures at a plurality of respective locations distributed over the surface, so as to create crystals of the semiconductor material at the respective locations. Typically, heating the semiconductor material includes directing a beam of radiation toward the surface at each of the locations so as to locally melt the semiconductor material. Additionally or alternatively, providing the layer of the semiconductor material includes creating a plurality of islands of the semiconductor material in respective positions on the surface that are adjacent to the respective locations of the capillary structures.

Typically, the capillary structure includes a groove. The groove may extend at least partially beneath the surface. Alternatively or additionally, the groove may be built at least partly above the surface.

In one embodiment, forming the capillary structure includes etching a first dielectric layer on the surface of the substrate to define the groove, and depositing a second dielectric layer over the groove after etching the first dielectric layer, so as to reduce a width of the groove. In this embodiment, etching the first dielectric layer includes defining an indentation in communication with the groove, and providing the layer of the semiconductor material includes depositing the semiconductor material in the indentation.

In another embodiment, forming the capillary structure includes etching the semiconductor material to create a protuberance on the surface at a location of the groove, depositing a layer of dielectric material over the etched semiconductor material, directionally etching the dielectric material so as to form dielectric spacers on the surface surrounding the protuberance, and removing the semiconductor material from between the dielectric spacers so as to create the groove. Typically, the protuberance at the location of the groove includes a first protuberance, and etching the semiconductor material includes creating a second protuberance in communication with the first protuberance, so that directionally etching the dielectric material forms the dielectric spacers surrounding the first and second protuberances, and removing the semiconductor material includes etching away the first protuberance without removing the second protuberance.

There is also provided, in accordance with an embodiment of the present invention, an assembly for use in producing a semiconductor device, including: a substrate; a layer of a semiconductor material disposed over at least a portion of a surface of a substrate; and a capillary structure, which is formed along the surface of the substrate in communication with the semiconductor material but is at least partially empty of the semiconductor material.

Typically, the capillary structure is adapted so that upon heating the semiconductor material to a melt, the semiconductor material flows into the capillary structure, and so that as the semiconductor material cools after the heating, a crystal is seeded in the capillary structure and spreads from the capillary structure through an area of the semiconductor material.

In a disclosed embodiment, the capillary structure includes a plurality of non-contiguous capillary structures at a plurality of respective locations distributed over the surface, and the semiconductor material includes a plurality of islands of the semiconductor material in respective positions on the surface that are adjacent to the respective locations of the capillary structures.

The present invention will be more fully understood from the following detailed description of the embodiments thereof, taken together with the drawings in which:

### BRIEF DESCRIPTION OF THE DRAWINGS

FIG. 1 is a schematic top view of an assembly used in producing a semiconductor device, in accordance with an embodiment of the present invention;

FIG. 2 is a schematic side view of a laser processing system, in accordance with an embodiment of the present invention;

FIGS. 3A-3D are schematic detail views of a silicon island and capillary structure, showing stages in a process of thin film crystallization, in accordance with an embodiment of the present invention;

FIG. 4 is a flow chart that schematically illustrates a process for fabricating single-crystal islands of silicon, in accordance with an embodiment of the present invention;

FIGS. 5A-5E are schematic, sectional views of a substrate, taken along the line marked V-V in FIG. 3A, illustrating successive steps in the process of FIG. 4;

FIG. 6 is a flow chart that schematically illustrates a process for fabricating single-crystal islands of silicon, in accordance with another embodiment of the present invention; and

FIGS. 7A-7G are schematic, sectional views of a substrate, taken along the line marked V-V in FIG. 3A, illustrating successive steps in the process of FIG. 6.

### DETAILED DESCRIPTION OF EMBODIMENTS

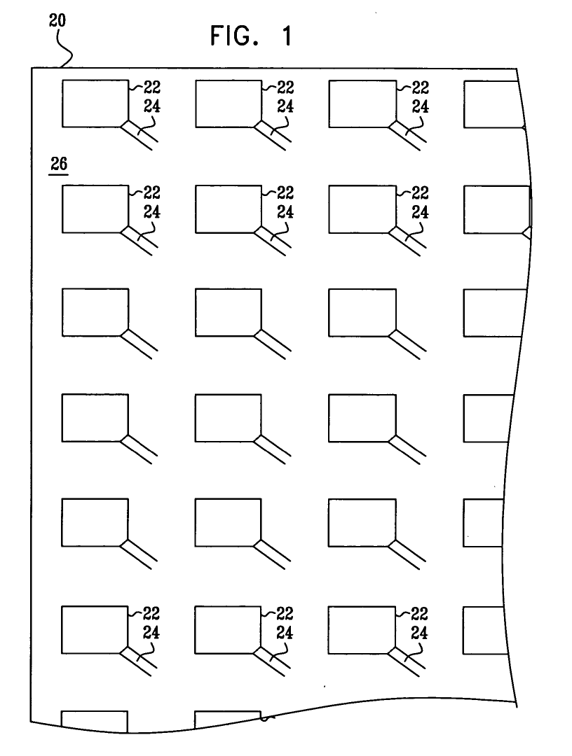

FIG. 1 is a schematic top view of an assembly 20 for use in producing a semiconductor device, in accordance with an embodiment of the present invention. For example, the semiconductor device may comprise a flat panel display, which is formed on a substrate 26, typically comprising glass. In this case, the final device is to comprise an array of thin film transistors, each serving one of the pixels of the display. For this purpose, an array of islands 22 of amorphous silicon (a-Si), or any other suitable semiconductor device precursor, is formed on the surface of the substrate. Typically, each island 22 is about 10-20 μm across, and the a-Si layer is about 50 nm thick. A capillary structure, typically in the form of a groove 24, is formed on the substrate adjacent to each of the islands. Grooves 24 are typically about 100 nm across, and are initially at least partly empty of the a-Si. Such grooves may be formed in the surface of substrate 26, or built-up above the surface of substrate 26. As shown in the FIG., the grooves are mutually non-contiguous. Methods for fabricating islands 22 and grooves 24 and the use of these structures in creating large-grain Si crystals on substrate 26 are described in detail hereinbelow.

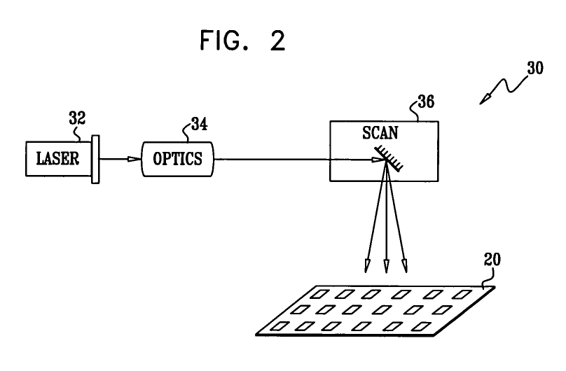

FIG. 2 is a highly simplified schematic side view of a system 30 for processing assembly 20, in accordance with an embodiment of the present invention. Systems of this sort are described in detail, for example, in the above-mentioned U.S. Pat. No. 6,573,531 and PCT Patent Publication Wo 03/071344 A1. Briefly, system 30 comprises a laser 32, which may emit ultraviolet, visible or infrared radiation, or radiation in a combination of these ranges. The radiation wavelength is typically selected so that the radiation is strongly absorbed by Si, but is poorly absorbed by the materials used to form grooves 24 (for example, SiO₂ and glass, as described below). Ultraviolet radiation, for example, meets this criterion. Optics 34 split the laser beam into multiple sub-beams, which are directed by at least one laser beam positioner, schematically depicted as a scanner 36, to impinge on the locations of islands 22 on substrate 26, and thus to selectively heat the islands. Alternatively, other methods of selective heating may be used. For example, microwave irradiation may be used to heat predefined silicon islands on a dielectric substrate, such as glass or plastic.

The energy incident on each island is typically sufficient to fully melt the a-Si. The molten Si flows from each island into the corresponding groove 24, causing orderly crystallization of the Si, as described below.

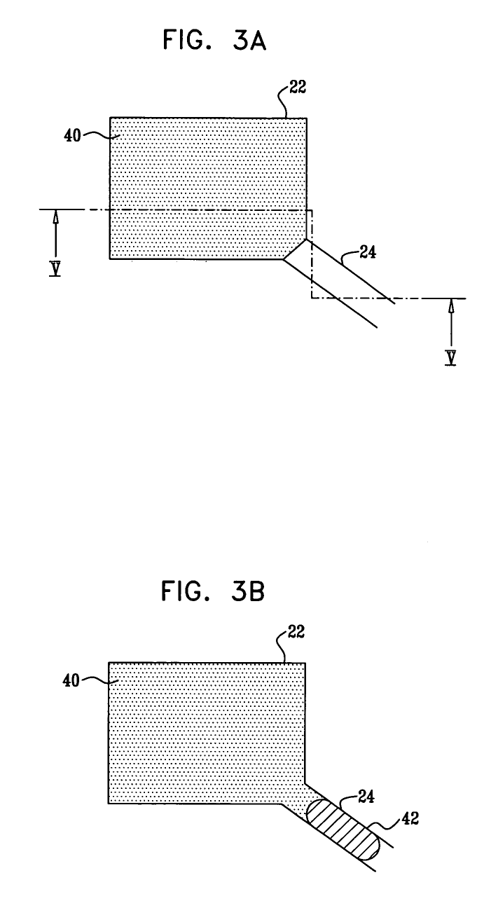

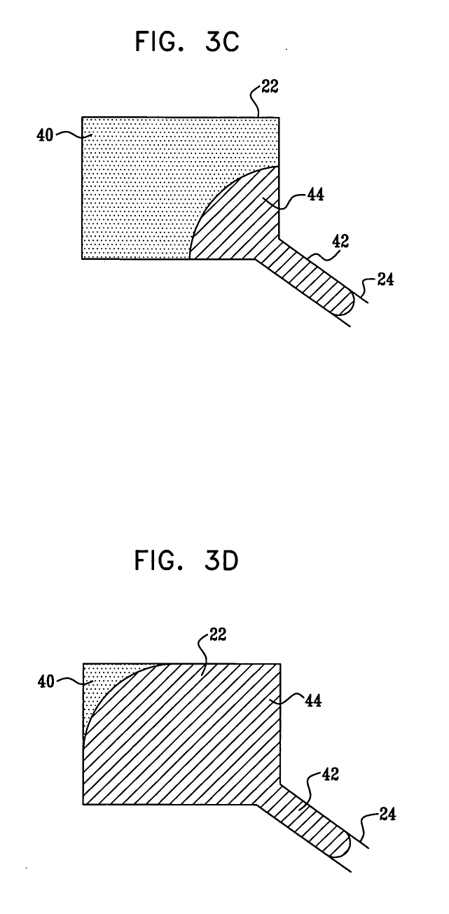

FIGS. 3A-3D are schematic detail views of one of islands 22 and its accompanying groove 24, showing stages in the process of Si crystallization, in accordance with an embodiment of the present invention. Initially, as shown in FIG. 3A, island 22 is filled with a-Si 40, while groove 24 is substantially empty. A beam from laser 32 brings a-Si 40 to a full melt. Typically, the laser heats the a-Si to a temperature sufficient to achieve an even, overheated melt, so that no nucleation centers remain in the melt. On the other hand, because the laser radiation is less strongly absorbed by the materials in the vicinity of groove 24, the groove remains relatively cool.

As shown in FIG. 3B, the melted Si begins to flow into groove 24 by capillary action. Assuming the groove to be coated internally with SiO₂, as described below, the wetting angle between molten Si and SiO₂ is about 80°, which is sufficient to create a melt flow into a capillary. Once the laser pulse ends, the relatively cooler temperature of groove 24 and the large surface/volume ratio of the molten Si in contact with the walls of the groove cause the Si to cool much faster in the groove than in the bulk of island 22. (The large surface/volume ratio also prevents supercooling of the molten silicon, which might otherwise cause uncontrolled, explosive crystallization.) As the leading edge of the Si flow in groove 24 cools, it forms a crystal seed 42.

As shown in FIGS. 3C and 3D, as Si 40 solidifies, a crystal 44 gradually grows from seed 42 through the area of island 22. The crystal orientation is thus determined by the orientation of groove 24. Although groove 24 is shown in these FIGS. as being connected to the corner of island 22, the groove may equally be connected to any side of the island, thus engendering different crystal orientations. The length and width of groove 24, as well as the degree of overheating of Si 40 during the melt by laser 32, can also be varied in order to control and optimize the crystallization process.

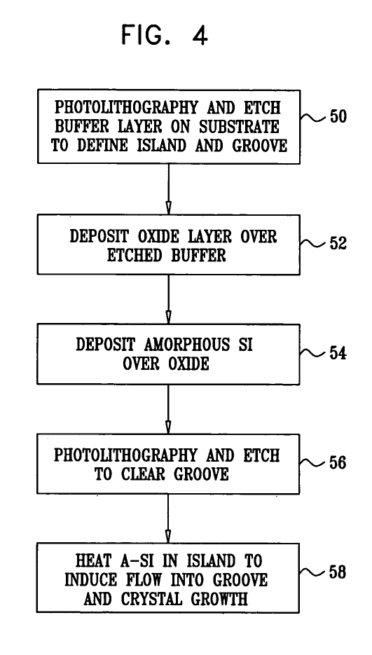

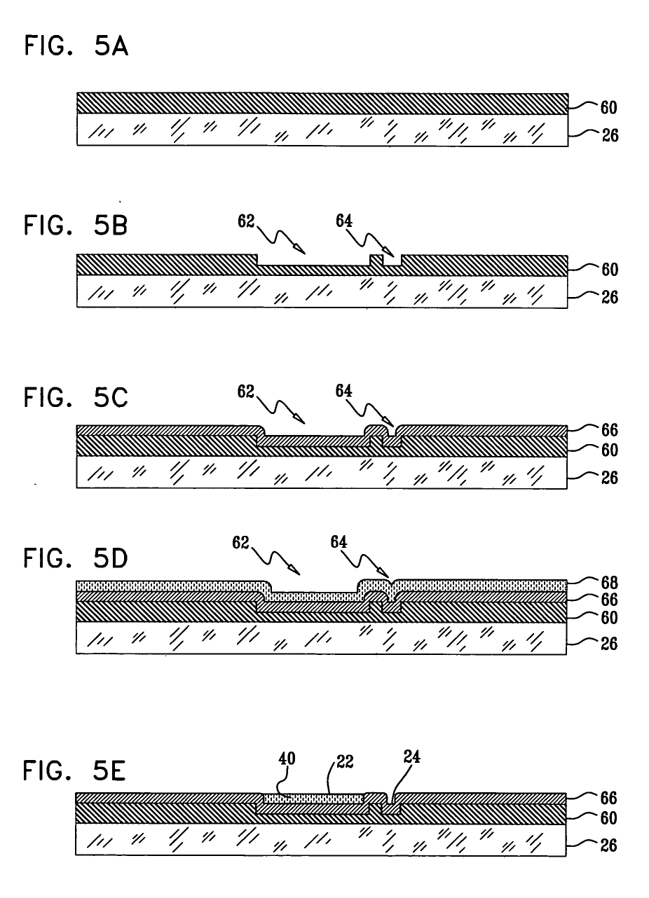

Reference is now made to FIGS. 4 and 5A-5E, which schematically illustrate a process for fabricating crystals 40 of Si in islands 22, in accordance with an embodiment of the present invention. FIG. 4 is a flow chart showing the steps in the process. FIGS. 5A-5E are schematic, sectional views of assembly 20, taken along the line V-V in FIG. 3A, showing the area of island 22 and groove 24 at successive stages in the process. The thicknesses of the layers shown in FIGS. 5A-5E are exaggerated for the sake of visual clarity.

Initially, as shown in FIG. 5A, a dielectric buffer layer 60, typically comprising SiO₂, is formed over substrate 26, using methods known in the art. A layer of photoresist (not shown in the FIG.) is deposited over buffer layer 60, and the locations of island 22 and groove 24 are defined by photolithography on the photoresist, at a first lithography step 50. The unexposed photoresist is removed, and the underlying area of layer 60 is etched to create indentations 62 and 64 at the locations of island 22 and groove 24, as shown in FIG. 5B. These indentations extend at least partly below the surface of substrate 26 (as defined in this case by buffer layer 60). The remaining photoresist is then cleaned off the surface. The width of indentation 64 following this step is typically about 500 nm.

In order to reduce the width of indentation 64 to about 100 nm, an additional layer 66 of SiO₂ is deposited over the etched buffer layer 60, at an oxide deposition step 52. Typically, layer 60 is deposited by chemical vapor deposition (CVD), to a thickness of about 200 nm. The result is shown in FIG. 5C.

Next, a layer 68 of a-Si is deposited over layer 66, typically by CVD, as well, at a silicon deposition step 54. The a-Si fills both of indentations 62 and 64, as shown in FIG. 5D. To remove the a-Si from indentation 64 and from the remaining region outside indentation 62, a new layer of photoresist is deposited over layer 68, and the area of island 22 is once again defined by photolithography, at a second lithography step 56. In this case, however, the area of island 22 is exposed in the lithography step, while the surrounding area (including the area of groove 24) is not. Therefore, when the unexposed photoresist is removed and the underlying material is etched, substantially all the a-Si outside island 22, including the a-Si in groove 24, is removed.

Upon completion of step 56 and removal of the remaining photoresist, assembly 20 has the form shown in FIG. 5E. Amorphous Si 40 remains in island 22, but not in groove 24. Due to the added coating of layer 66, the width of the groove is about 100 nm, as desired. The a-Si in island 22 is then heated, as described above, at a heating step 58, causing capillary flow into groove 24 and formation of a single Si crystal in the area of island 22.

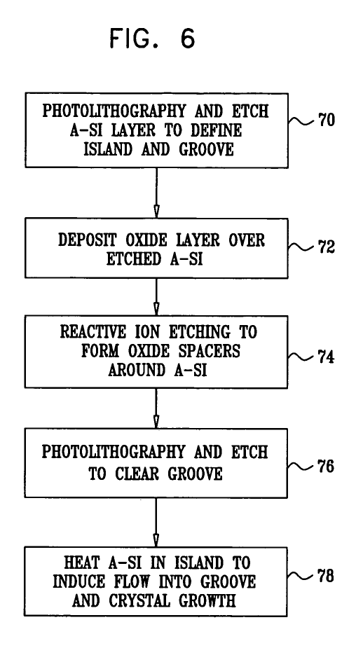

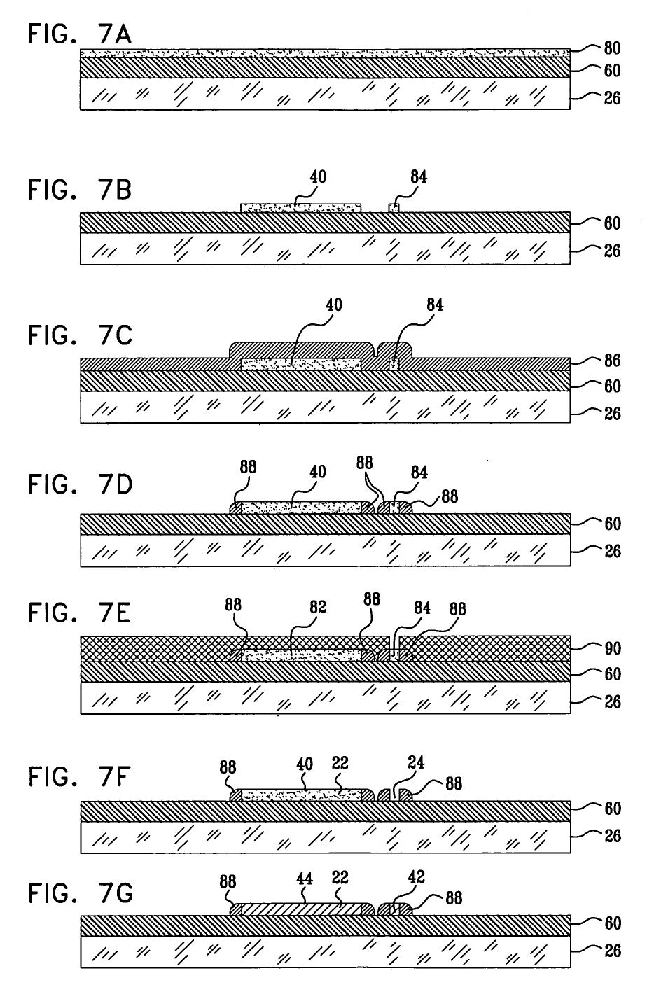

FIGS. 6 and 7A-7G schematically illustrate a process for fabricating crystals 40 of Si in islands 22, in accordance with another embodiment of the present invention. As in the preceding embodiment, FIG. 6 is a flow chart showing the steps in the process, and FIGS. 7A-7G are schematic, sectional views taken along the line V-V in FIG. 3A. The thicknesses of the layers shown in FIGS. 7A-7G are exaggerated for the sake of visual clarity. The present embodiment, as described below, uses oxide “fences” built-up to extend at least partially above substrate 26 in order to define the areas of island 22 and groove 24. This method is advantageous, by comparison with the preceding embodiment, in that it ensures that a-Si 40 in island 22 will have a more uniform thickness. Generally speaking, the greater the uniformity of the a-Si, the less will be the likelihood that undesired nucleation centers will develop in the island as the molten Si cools.

As shown in FIG. 7A, the process in this embodiment begins with formation of buffer layer 60 over substrate 26, and above it a thin layer 80 of a-Si. Typically, layer 80 is deposited by plasma enhanced chemical vapor deposition (PECVD), as is known in the art, although any other suitable methodology for depositing layer 80 may be employed. Photolithography and etching are then applied (using a photoresist layer, as described above), to define the locations of island 22 and groove 24, at a first lithography step 70. As shown in FIG. 7B, this step results in formation of a-Si protuberances on buffer layer 60. The location of groove 24 at this point is marked by a line 84 of a-Si, which is approximately equal in width to the desired width of the groove.

An additional layer 86 of SiO₂ is deposited over the a-Si protuberances, at an oxide deposition step 72. This step may be accomplished by CVD using tetra-ethyl-ortho-silicate (TEOS) vapor. The result is shown in FIG. 7B. Note that as a consequence of the deposition process, the thickness of layer 86 in the vertical direction (i.e., the direction perpendicular to the surface of substrate 26) is greater at the edges of the a-Si protuberances than elsewhere on the surface. Reactive ion etching (RIE) is then applied to remove most of layer 86, at an etching step 74. The etching process at this step uses highly anisotropic plasma etching, so that the vertical etch rate is typically at least ten times the horizontal etch rate. The result, as shown in FIG. 7D, is that substantially all of SiO₂ layer 86 is removed from the surface, except for spacers 88 at the edges of the a-Si protuberances, where layer 86 was initially thicker.

The a-Si in line 84 is next removed from groove 24 between spacers 88, at a second lithography step 76. For this purpose, a layer of photoresist 90 is again deposited over the surface of assembly 20. Photolithography is then used to define the area of groove 24, as shown in FIG. 7E. The a-Si is etched out of the groove, and the remaining photoresist is then cleaned off the surface. The result of this step is shown in FIG. 7F, in which a-Si 40 remains in island 22, while groove 24 is substantially empty of silicon. The island and groove are bounded by a fence made of SiO₂ spacers 88. The a-Si in island 22 is heated, as described above, at a heating step 78, causing capillary flow into groove 24 and formation of Si crystal 44 in the area of island 22, as shown in FIG. 7G.

Spacers 88 remain on the surface of substrate 26 following the crystallization process. Spacers of this type are also useful in protecting the lightly-doped drain (LDD) area of the thin film transistor that is formed over silicon crystal 44 from further doping.

Although the embodiments described above make use of certain specific substrate and semiconductor materials (glass and silicon), the principles of the present invention may similarly be applied on different types of substrates and using different semiconductor materials. For example, the semiconductor material may comprise germanium, while the substrate may comprise substantially any suitable insulator, semiconductor or metal material. Other processes may be used to create the capillary structures, which may have the form of grooves, as described above, or may comprise tubes or other types of capillaries arranged along the surface of the substrate. Semiconductor crystals formed in accordance with the present invention may be used advantageously not only in thin film transistors, but also in devices of other types, such as resistors and capacitors. All these variations are considered to be within the scope of the present invention.

It will thus be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. A method for fabricating a semiconductor device, comprising:
providing a layer of a semiconductor material on at least a portion of a surface of a substrate;
forming along the surface a capillary structure, which is in communication with the semiconductor material but is at least partially empty of the semiconductor material;
heating the semiconductor material, so as to cause the semiconductor material to melt and flow into the capillary structure; and
allowing the semiconductor material to cool to form a crystal in the semiconductor material.

2. The method according to claim 1, wherein allowing the semiconductor material to cool causes the crystal to be seeded in the capillary structure and to spread from the capillary structure through an area of the semiconductor material.

3. The method according to claim 1, wherein heating the semiconductor material comprises bringing the semiconductor material to an overheated full melt.

4. The method according to claim 1, wherein providing the layer of the semiconductor material comprises depositing amorphous silicon (a-Si) on the surface.

5. The method according to claim 1, wherein forming the capillary structure comprises forming a plurality of non-contiguous capillary structures at a plurality of respective locations distributed over the surface, so as to create crystals of the semiconductor material at the respective locations.

6. The method according to claim 5, wherein heating the semiconductor material comprises directing a beam of radiation toward the surface at each of the locations so as to locally melt the semiconductor material.

7. The method according to claim 5, wherein providing the layer of the semiconductor material comprises creating a plurality of islands of the semiconductor material in respective positions on the surface that are adjacent to the respective locations of the capillary structures.

8. The method according to claim 1, wherein the capillary structure comprises a groove.

9. The method according to claim 8, wherein forming the capillary structure comprises forming the groove to extend at least partially beneath the surface.

10. The method according to claim 8, wherein forming the capillary structure comprises etching a first dielectric layer on the surface of the substrate to define the groove, and depositing a second dielectric layer over the groove after etching the first dielectric layer, so as to reduce a width of the groove.

11. The method according to claim 10, wherein etching the first dielectric layer comprises defining an indentation in communication with the groove, and wherein providing the layer of the semiconductor material comprises depositing the semiconductor material in the indentation.

12. The method according to claim 8, wherein forming the capillary structure comprises building the capillary structure at least partly above the surface.

13. The method according to claim 8, wherein forming the capillary structure comprises:
etching the semiconductor material to create a protuberance on the surface at a location of the groove;
depositing a layer of dielectric material over the etched semiconductor material;
directionally etching the dielectric material so as to form dielectric spacers on the surface surrounding the protuberance; and
removing the semiconductor material from between the dielectric spacers so as to create the groove.

14. The method according to claim 13, wherein the protuberance at the location of the groove comprises a first protuberance, and wherein etching the semiconductor material comprises creating a second protuberance in communication with the first protuberance, so that directionally etching the dielectric material forms the dielectric spacers surrounding the first and second protuberances, and wherein removing the semiconductor material comprises etching away the first protuberance without removing the second protuberance.

15. An assembly for use in producing a semiconductor device, comprising:
a substrate;
a layer of a semiconductor material disposed over at least a portion of a surface of a substrate; and
a capillary structure, which is formed along the surface of the substrate in communication with the semiconductor material but is at least partially empty of the semiconductor material.

16. The assembly according to claim 15, wherein the capillary structure is adapted so that upon heating the semiconductor material to a melt, the semiconductor material flows into the capillary structure.

17. The assembly according to claim 16, wherein the capillary structure and semiconductor material are arranged so that as the semiconductor material cools after the heating, a crystal is seeded in the capillary structure and spreads from the capillary structure through an area of the semiconductor material.

18. The assembly according to claim 15, wherein the semiconductor material comprises amorphous silicon (a-Si).

19. The assembly according to claim 15, wherein the capillary structure comprises a plurality of non-contiguous capillary structures at a plurality of respective locations distributed over the surface.

20. The assembly according to claim 19, wherein the semiconductor material comprises a plurality of islands of the semiconductor material in respective positions on the surface that are adjacent to the respective locations of the capillary structures.

21. The assembly according to claim 15, wherein the capillary structure comprises a groove.

22. The assembly according to claim 21, wherein the groove extends at least partially beneath the surface.

23. The assembly according to claim 21, and comprising first and second dielectric layers deposited on the surface, wherein the capillary structure is formed by etching the first dielectric layer on the surface of the substrate to define the groove, and depositing the second dielectric layer over the groove after etching the first dielectric layer, so as to reduce a width of the groove.

24. The assembly according to claim 23, wherein the first dielectric layer is etched to define an indentation in communication with the groove, and wherein the semiconductor material is deposited in the indentation.

25. The assembly according to claim 21, wherein the capillary structure comprises a protuberance built-up at least partially above the surface.

26. The assembly according to claim 21, and comprising a layer of dielectric material deposited on the surface, wherein the capillary structure is formed by etching the semiconductor material to create a protuberance on the surface at a location of the groove, depositing the layer of dielectric material over the etched semiconductor material, directionally etching the dielectric material so as to form dielectric spacers on the surface surrounding the protuberance, and removing the semiconductor material from between the dielectric spacers so as to create the groove.

27. The assembly according to claim 26, wherein the protuberance at the location of the groove comprises a first protuberance, and wherein the semiconductor material is etched to create a second protuberance in communication with the first protuberance, so that the dielectric spacers surround the first and second protuberances, and wherein the semiconductor material is removed from the groove by etching away the first protuberance without removing the second protuberance.
